(19) United States
(12) Patent Application Publication
(10) Pub. No.: US 2025/0311204 A1
(43) Pub. Date: Oct. 2, 2025

(54) SEMICONDUCTOR STRUCTURE AND METHOD FOR FABRICATING THE SAME

(71) Applicant: Fujian Jinhua Integrated Circuit Co., Ltd., Quanzhou City (CN)

(72) Inventors: XINYAN HONG, Quanzhou City (CN); Janbo Zhang, Quanzhou City (CN); Yu-Cheng Tung, Quanzhou City (CN)

(73) Assignee: Fujian Jinhua Integrated Circuit Co., Ltd., Quanzhou City (CN)

(21) Appl. No.: 18/659,009

(22) Filed: May 9, 2024

(30) Foreign Application Priority Data
Mar. 27, 2024 (CN) 202410364937.0

(51) Int. Cl. H10B 12/00

(52) U.S. Cl. CPC H10B 12/50; H10B 12/09

(57) ABSTRACT

A semiconductor structure includes a substrate, a plurality of first gate structures, two first spacers, a plurality of second gate structures, two second spacers, a plurality of gate contact structures and a plurality of insulating structures. The plurality of first gate structures are disposed on the substrate. The two first spacers are disposed oppositely on two side surfaces of one of the plurality of first gate structures. The plurality of second gate structures are disposed on the substrate. The plurality of first gate structures and the plurality of second gate structures are alternately arranged in a first direction. The two second spacers are disposed oppositely on two side surfaces of one of the plurality of second gate structures. The plurality of insulating structures are disposed between the plurality of gate contact structures and respectively disposed on the plurality of second gate structures.

### BACKGROUND OF THE INVENTION

### 1. Field of the Invention

The present disclosure relates to a semiconductor structure and a method for fabricating the same, and more particularly, to a semiconductor structure including a gate structure disposed in a peripheral region and a method for fabricating the same.

### 2. Description of the Prior Art

With the vigorous development of frontier technologies, such as Internet of Things (IoT), edge computing and artificial intelligence, huge information processing capabilities are required, and memories play an indispensable role.

Dynamic random access memory (DRAM) is a common random access memory, which is a kind of volatile memory, and includes an array region composed of a plurality of memory cells and a peripheral region composed of control circuits. Each of the memory cells is composed of a transistor and a capacitor electrically connected with the transistor. The transistor controls the storage or release of charges in the capacitor to achieve the purpose of storing data. The control circuits can be addressed to each of the memory cells to control the access of data of each of the memory cells through word lines (WLs) bit lines (BLs) that span the array region and are electrically connected with each of the memory cells.

However, as the line width of the semiconductor fabrication process continues to shrink, more challenges and bottlenecks have emerged in the semiconductor fabrication process. Therefore, how to improve the structure of the memory, such as having lower manufacturing difficulty and higher process yield, has become an important issue for relevant industries.

### SUMMARY OF THE INVENTION

According to one embodiment of the present disclosure, a semiconductor structure includes a substrate, a plurality of first gate structures, two first spacers, a plurality of second gate structures, two second spacers, a plurality of gate contact structures and a plurality of insulating structures. The plurality of first gate structures are disposed on the substrate. The two first spacers are disposed oppositely on two side surfaces of one of the plurality of first gate structures. The plurality of second gate structures are disposed on the substrate, in which the plurality of first gate structures and the plurality of second gate structures are alternately arranged in a first direction. The two second spacers are disposed oppositely on two side surfaces of one of the second gate structures. The plurality of gate contact structures are respectively disposed on the plurality of first gate structures. The plurality of insulating structures are disposed between the plurality of gate contact structures and respectively disposed on the plurality of second gate structures. A height of at least one of the two first spacers is lower than a height of at least one of the two second spacers.

According to another embodiment of the present disclosure, a method for fabricating a semiconductor structure includes steps as follows. A substrate is provided. A plurality of first gate structures and a plurality of second gate structures alternately arranged in a first direction are formed on the substrate. Two first spacers are formed on two side surfaces of one of the first gate structures and two second spacers on two side surfaces of one of the second gate structures. An etching step is performed to remove a portion of at least one of the two first spacers, so that a height of the at least one of the two first spacers is lower than a height of at least one of the two second spacers. A plurality of gate contact structures respectively on the first gate structures are formed. A plurality of insulating structures between the gate contact structures and respectively on the second gate structures are formed.

According to yet another embodiment of the present disclosure, a semiconductor structure includes a substrate, a gate structure, two contact plugs and a gate contact structure. The gate structure is disposed on the substrate. The two contact plugs are disposed on the substrate and at two sides of the gate structure. The gate contact structure is disposed on the gate structure, in which the gate contact structure is simultaneously connected with the two contact plugs and the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 15 are schematic diagrams showing a structure of a semiconductor structure during a fabricating process according to an embodiment of the present disclosure, in which FIG. 1 is a schematic plan view of the semiconductor structure, FIG. 2 and FIG. 13 are enlarged schematic plan views of a partial region shown in FIG. 1, FIG. 3, FIG. 6, FIG. 7, FIG. 8, FIG. 9, FIG. 11 and FIG. 14 are schematic cross-sectional views of the semiconductor structure taken along a line A-A′ shown in FIG. 2 or FIG. 13, FIG. 4, FIG. 5, FIG. 10, FIG. 12 and FIG. 15 are schematic cross-sectional views of the semiconductor structure taken along a line B-B′ shown in FIG. 2 or FIG. 13.

FIG. 16 is a schematic cross-sectional view of a semiconductor device according to another embodiment of the present disclosure, and the view angle thereof is identical to that of FIG. 15.

FIG. 17 is a schematic cross-sectional view of a semiconductor device according to yet another embodiment of the present disclosure, and the view angle thereof is identical to that of FIG. 15.

FIG. 18 is a schematic cross-sectional view of a semiconductor device according to yet another embodiment of the present disclosure, and the view angle thereof is identical to that of FIG. 15.

FIG. 19 to FIG. 21 are schematic diagrams showing a structure of the semiconductor structure shown in FIG. 18 during a fabricating process, and the view angle thereof is identical to that of FIG. 15.

FIG. 22 is a schematic cross-sectional view of a semiconductor device according to yet another embodiment of the present disclosure, and the view angle thereof is identical to that of FIG. 15.

FIG. 23 to FIG. 25 are schematic diagrams showing a structure of the semiconductor structure shown in FIG. 22 during a fabricating process, and the view angle thereof is identical to that of FIG. 15.

### DETAILED DESCRIPTION

In order to enable the skilled persons in the art to better understand the present disclosure, hereinafter preferred embodiments with drawings are provided for illustrating the present disclosure and the effect to be achieved. It should be noted that the technical features in different embodiments described in the following can be replaced, recombined, or mixed with one another to constitute another embodiment without departing from the spirit of the present disclosure.

For the convenience of explanation and comprehension the semiconductor structure according to the present disclosure, the spatial reference directions, such as the first direction D1, the second direction D2, the third direction D3 and the fourth direction D4 are shown in the drawings, in which the first direction D1, the second direction D2 and the fourth direction D4 are parallel to a surface of the substrate 100, and the first direction D1 and the second direction D2 are perpendicular to each other and are different from the fourth direction D4. An angle between the second direction D2 and the fourth direction D4 may range from 15 degrees to 75 degrees, but not limited thereto. The third direction D3 is perpendicular to the surface of the substrate 100. Each of the first direction D1, the second direction D2, and the fourth direction D4 may be called a horizontal direction, and the third direction D3 may be called a vertical direction.

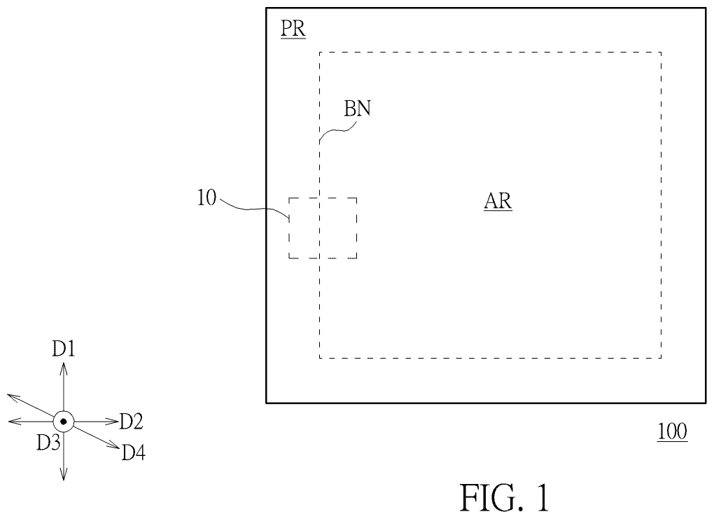

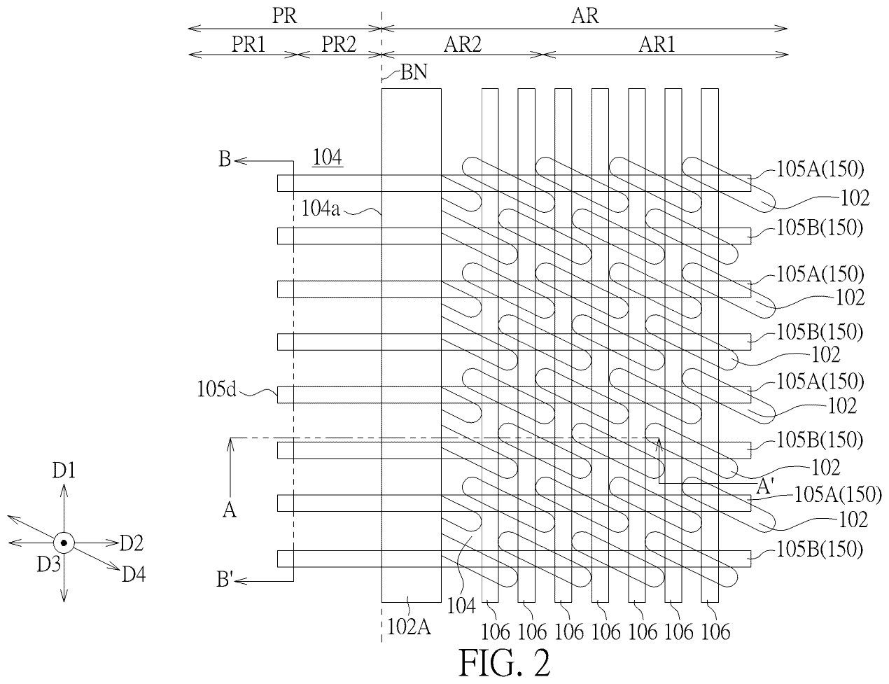

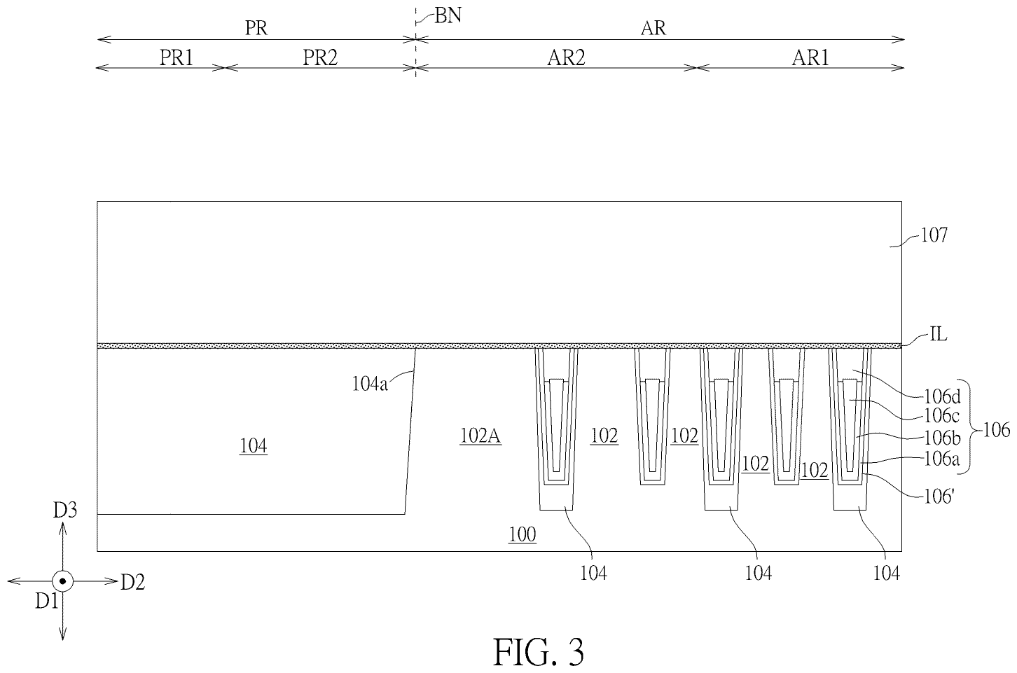

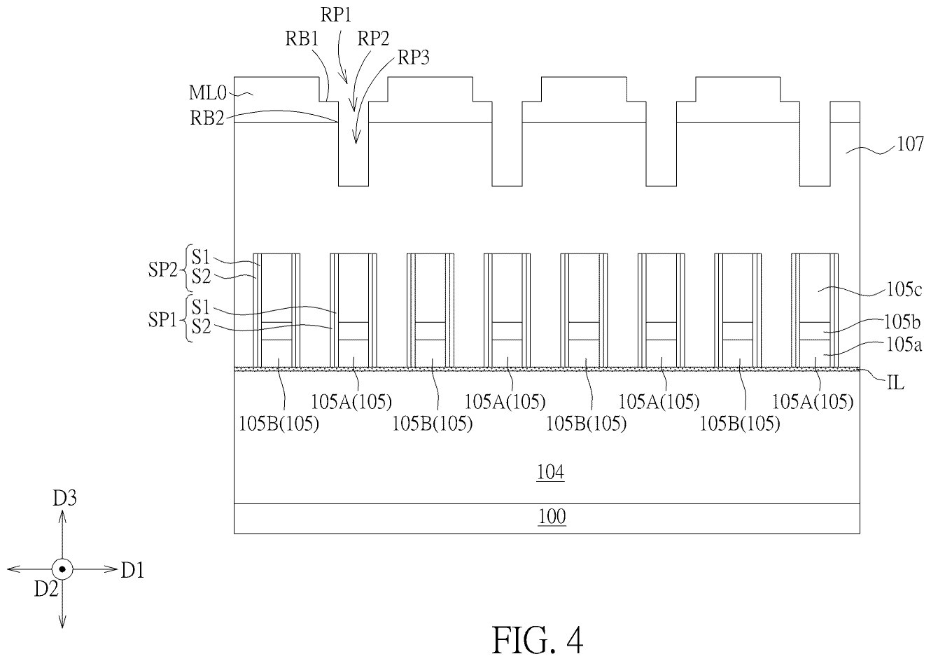

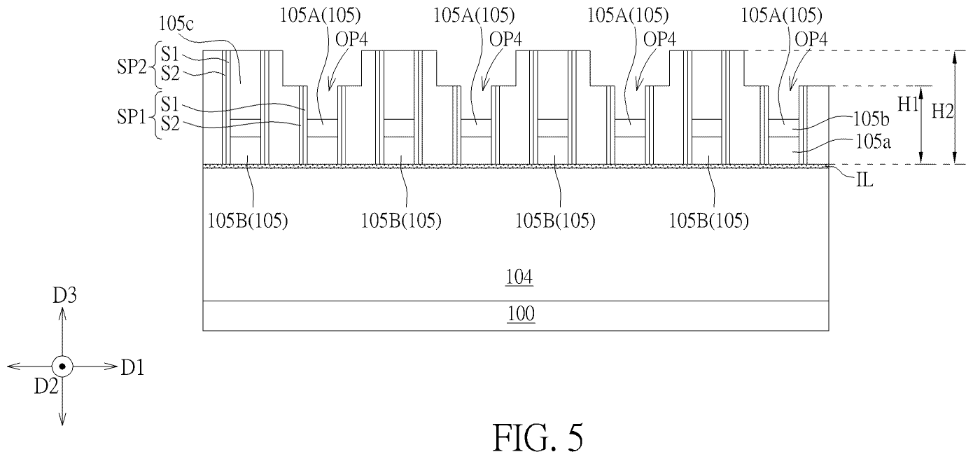

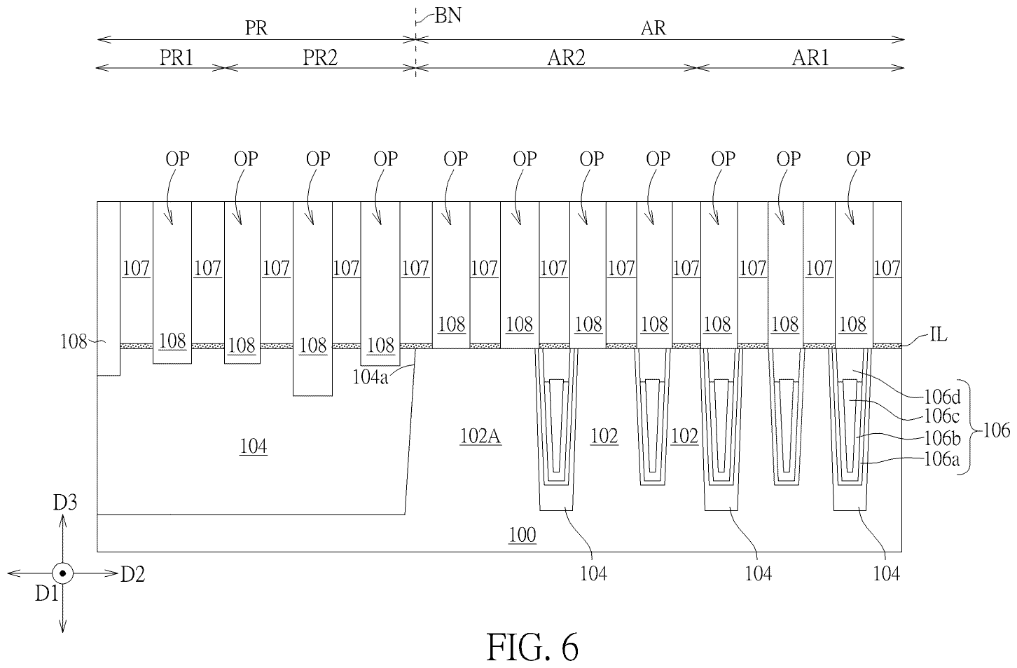

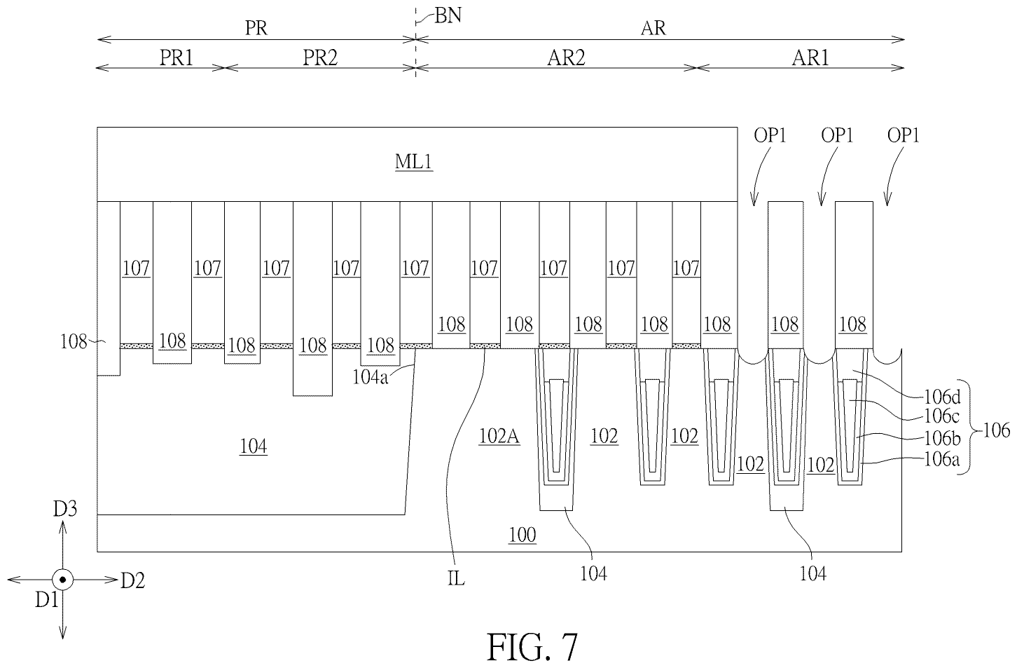

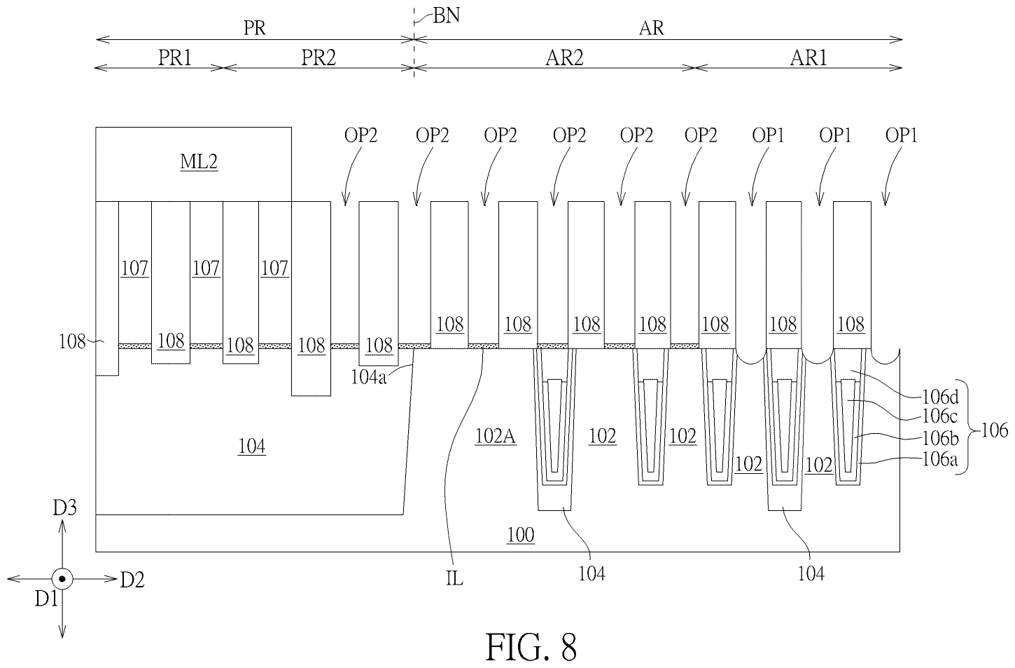

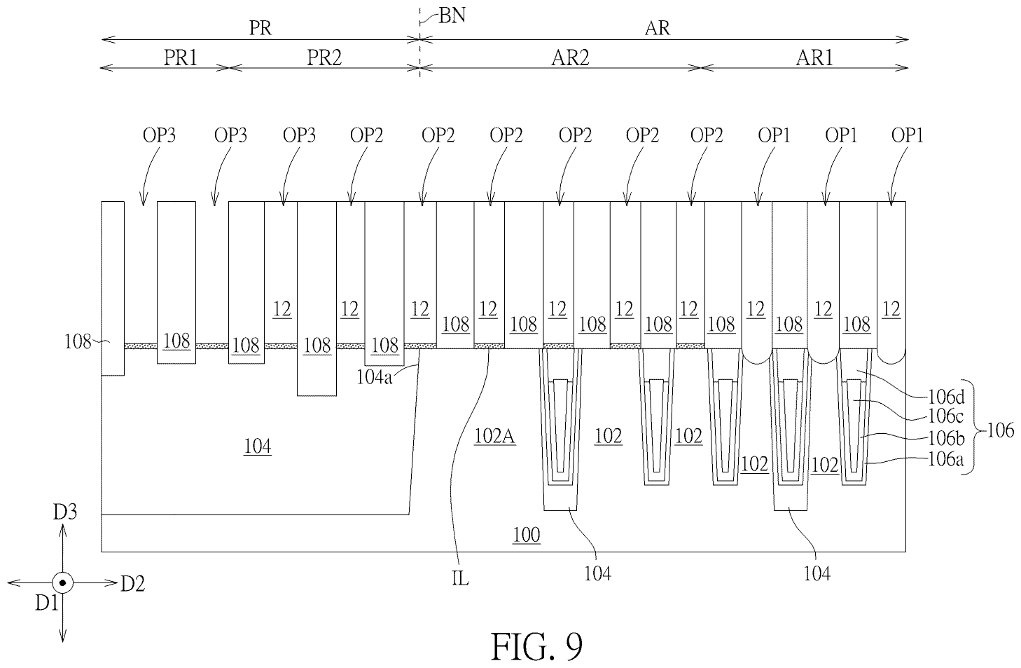

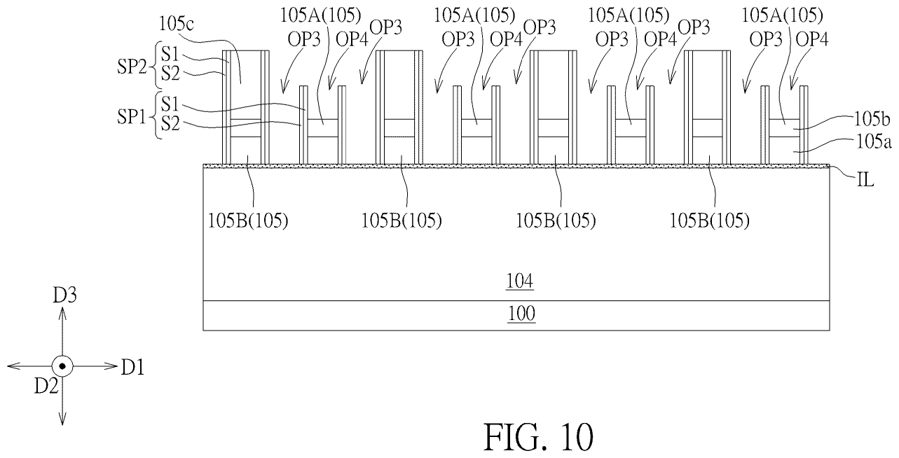

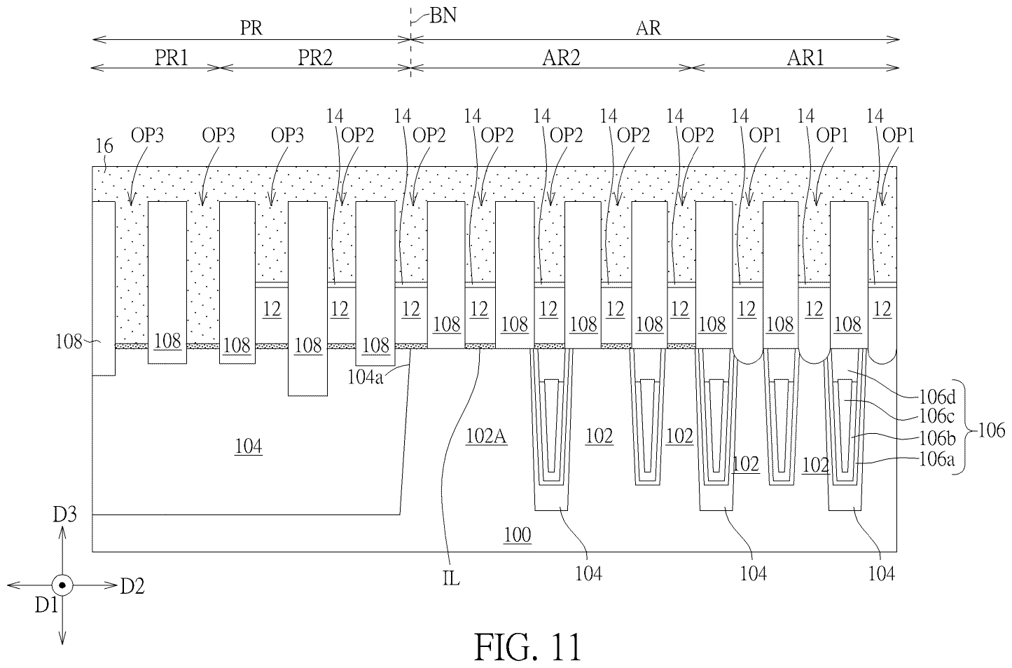

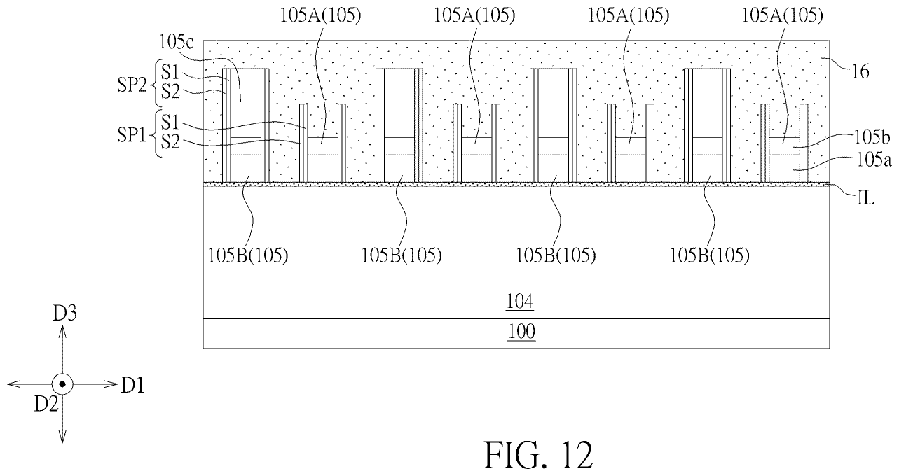

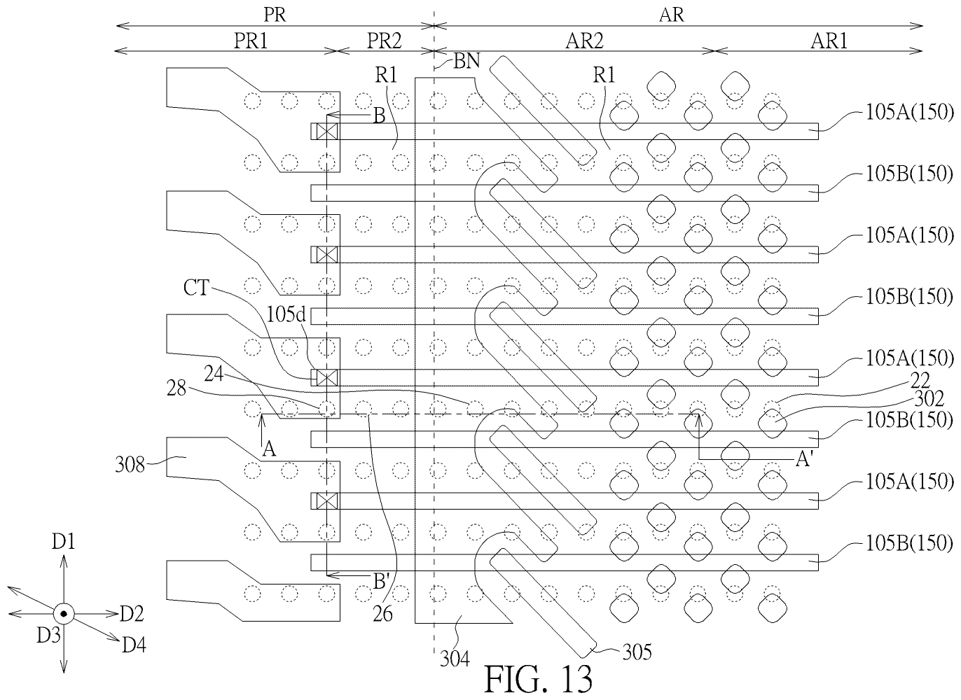

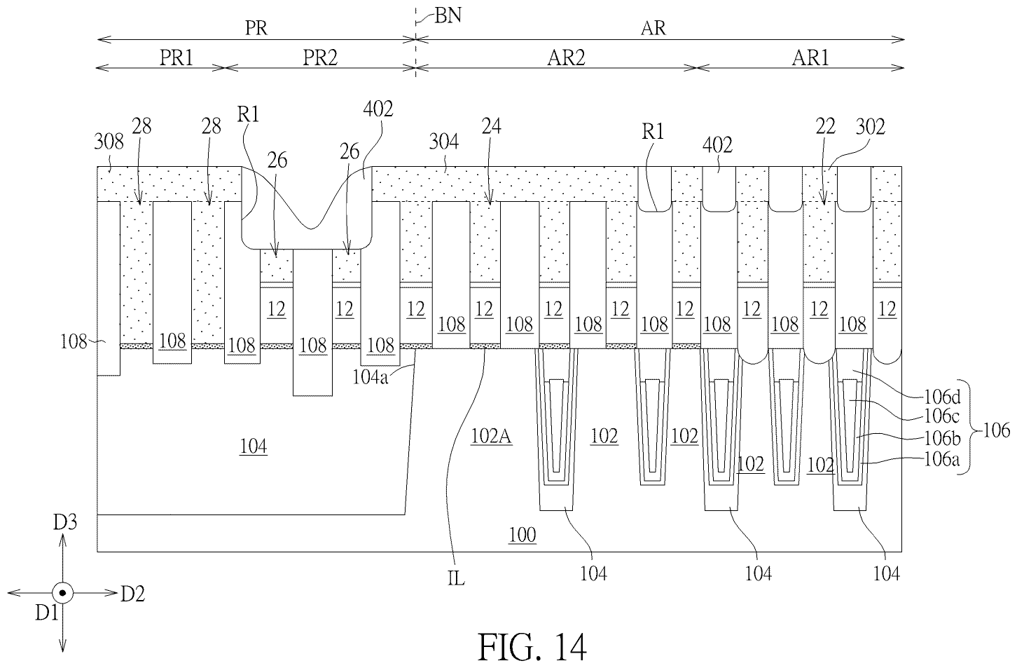

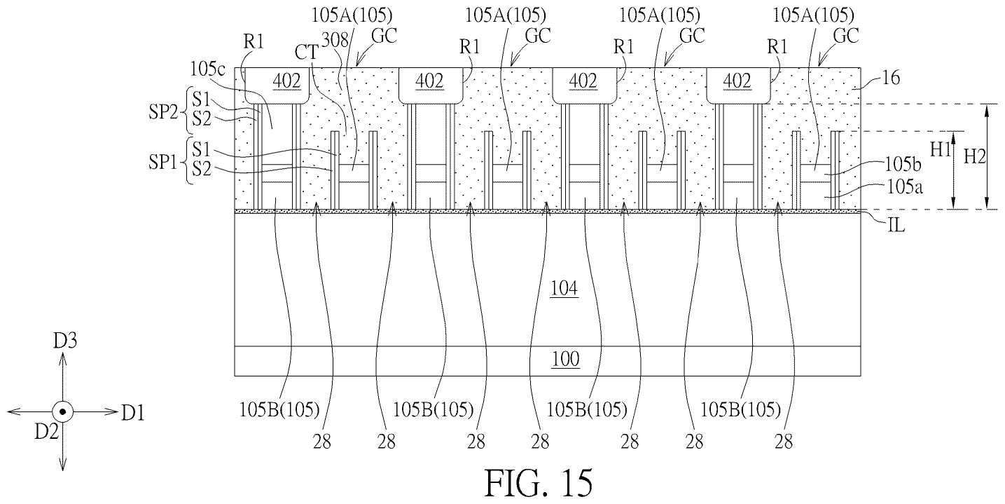

FIG. 1 to FIG. 15 are schematic diagrams showing a structure of a semiconductor structure during a fabricating process according to an embodiment of the present disclosure, in which FIG. 1 is a schematic plan view of the semiconductor structure, FIG. 2 and FIG. 13 are enlarged schematic plan views of a partial region 10 shown in FIG. 1, FIG. 3, FIG. 6, FIG. 7, FIG. 8, FIG. 9, FIG. 11 and FIG. 14 are schematic cross-sectional views of the semiconductor structure taken along a line A-A′ shown in FIG. 2 or FIG. 13, and FIG. 4, FIG. 5, FIG. 10, FIG. 12 and FIG. 15 are schematic cross-sectional views of the semiconductor structure taken along a line B-B′ shown in FIG. 2 or FIG. 13. The line A-A′ extends along the second direction D2 and is located between two latitudinal gate structures 105, and the line B-B′ extends along the first direction D1 and passes across ends 105d of the latitudinal gate structures 105 located in the peripheral region PR. In order to simplify the drawings, some components may be omitted and not shown in each of the drawings. For example, in FIG. 2 and FIG. 13, at least the first spacers SP1 and the second spacers SP2 are omitted and not shown. The semiconductor structure according to the present disclosure may be used to fabricate dynamic random access memory (DRAM) including stacked capacitors. The present disclosure may also be used to fabricate other types of semiconductor components without departing from the spirit of the present disclosure.

Please refer to FIG. 1, a substrate 100 is firstly provided. The substrate 100 may be, for example, a silicon substrate, an epitaxial silicon substrate, a silicon germanium substrate, a silicon carbide substrate or silicon-on-insulator (SOI) substrate, but not limited thereto. The substrate 100 is defined with a unit region AR and a peripheral region PR. The unit region AR may also be called an array region, which is a region disposed with an array of memory cells. The memory cells may be, for example, dynamic random access memory cells. The peripheral region PR is disposed adjacent to the unit region AR to separate the unit region AR from other circuit regions of the substrate 100. In some embodiments, the peripheral region PR is also a region in which word lines and bit lines that control the operation of the memory cells are electrically connected with peripheral circuits. In some embodiments, the peripheral region PR may further include peripheral circuits, such as drivers, buffers, amplifiers, and decoders, but not limited thereto. It should be noted that the shapes and layouts of the peripheral region PR and the unit region AR shown in FIG. 1 are examples for the convenience of explanation and are not used to limit the present disclosure. A boundary BN is included between the unit region AR and the peripheral region PR.

Please refer to FIG. 2. The unit region AR may be further divided into a main unit region AR1 and a transition unit region AR2 between the main unit region AR1 and the boundary BN. The peripheral region PR may be further divided into a main peripheral region PR1 and a transition peripheral region PR2 between the main peripheral region PR1 and the boundary BN. An isolation structure 104 may be disposed in the substrate 100. The isolation structure 104 defines a plurality of active regions 102 in the unit region AR of the substrate 100 and an active region 102A substantially disposed along the boundary BN. The isolation structure 104 may be, for example, a shallow trench isolation (STI) structure, which may include a single layer or multiple layers of dielectric material, such as silicon oxide (SiO₂), silicon nitride (SiN), or a combination thereof, but not limited thereto. The active regions 102 respectively extend along the fourth direction D4 and are parallel to each other to form an active region array. Some of the active regions 102 have one ends connected with the active region 102A. The peripheral region PR mainly includes the isolation structure 104 disposed in the substrate 100, and an edge 104a of the isolation structure 104 is substantially extended along the boundary BN and aligned with the boundary BN. However, the present disclosure is not limited thereto. In other embodiments, the peripheral region PR of the substrate 100 may not be disposed with the isolation structure 104.

Please refer to FIG. 2 and FIG. 3 simultaneously. A plurality of longitudinal gate structures 106 may be formed in the substrate 100. The plurality of longitudinal gate structures 106 extend along the first direction D1 and pass through the active regions 102 and the isolation structure 104, and the plurality of longitudinal gate structures 106 are parallel with each other in the second direction D2, so as to divide each of the active regions 102 into two end portions and a middle portion. The longitudinal gate structures 106 may be, for example, word lines that controls the operation of the memory cells, and the portions of the longitudinal gate structures 106 that pass through the active regions 102 may be the gates of the transistors of the memory cells, and the portions of the longitudinal gate structures 106 that pass through the isolation structure 104 may be the passing gates. According to an embodiment of the present disclosure, the steps for fabricating the longitudinal gate structures 106 may include forming trenches 106′ that pass through the isolation structure 104 and the active regions 102 in the substrate 100, forming a gate insulating layer 106a on the bottom surfaces and the side surfaces of the trenches 106′, forming a work function metal layer 106b and a conductive layer 106c to fill the lower portions of the trenches 106′, and then forming an insulating cap layer 106d to fill the upper portions of the trenches 106′, so as to obtain the longitudinal gate structures 106. Each of the insulating cap layer 106d and the gate insulating layer 106a may include a dielectric material, such as silicon dioxide (SiO₂), silicon nitride (SiN), or a combination thereof, but not limited thereto. In some embodiments, the gate insulating layer 106a may include a dielectric material of a metal oxide with a high-k constant, but not limited thereto. A material of the work function metal layer 106b may include a work function metal, such as titanium nitride (TiN) or a combination thereof, but not limited thereto. The conductive layer 106c may include a metal material such as tungsten (W), but not limited thereto.

Please refer to FIG. 3 and FIG. 4 simultaneously. After forming the longitudinal gate structures 106, an insulating layer IL is formed on the substrate 100 to completely cover the active regions 102 and the isolation structure 104. The insulating layer IL may include a single-layer structure or a multi-layer structure. For example, the multi-layer structure may include an oxide layer, a nitride layer and an oxide layer from bottom to top, but not limited thereto. Next, as shown in FIG. 2 and FIG. 4, a plurality of latitudinal gate structures 105 may be formed on the substrate 100. The fabrication of the latitudinal gate structures 105 may include steps as follows. First, a mask layer (not shown) is formed on the insulating layer IL. The mask layer includes a plurality of openings respectively corresponding to the middle portions of the active regions 102, and then portions of the insulating layer IL exposed from the openings are etched to expose the middle portions of the active regions 102. Afterward, the mask layer is removed, and a latitudinal gate stack material and a mask layer 105c are formed on the substrate 100. The latitudinal gate stack material includes a semiconductor layer 105a and a conductive layer 105b from bottom to top. Next, a patterning process (such as photolithography and etching process) is performed on the latitudinal gate stack material and the mask layer 105c to remove redundant portions of the semiconductor layer 105a, the conductive layer 105b and the mask layer 105c, so as to obtain the latitudinal gate structures 105 and the mask layer 105c on the latitudinal gate structures 105. The plurality of latitudinal gate structures 105 are arranged parallel to each other in the first direction D1 and extend along the second direction D2 to pass through the unit region AR to the peripheral region PR, and the end portions 105d of the latitudinal gate structures 105 are disposed on the main peripheral region PR1. The latitudinal gate structures 105 may be, for example, bit lines that control the operation of the memory cells. The plurality of latitudinal gate structures 105 may include a plurality of first gate structures 105A and a plurality of second gate structures 105B alternately arranged on the substrate 100 in the first direction D1. At this stage, the structures of the first gate structures 105A and the second gate structures 105B are the same. However, the structures of the first gate structures 105A and the second gate structures 105B may be different with the subsequent processes, and details thereof may refer to the relevant description below.

Next, two first spacers SP1 are formed on two side surfaces of the first gate structures 105A and two second spacers SP2 are formed on two side surfaces of the second gate structures 105B to protect the first gate structures 105A and the second gate structures 105B and to provide the function of electrical isolation. The latitudinal gate structures 105 overlap and directly contact the middle portions of the active regions 102. Each of the first spacers SP1 and the second spacers SP2 may include a multi-layer structure. Herein, each of the first spacers SP1 and the second spacers SP2 exemplarily includes a first insulating layer S1 and a second insulating layer S2, in which the first insulating layer S1 directly contacts the side surfaces of the first gate structures 105A or the side surfaces of the second gate structures 105B, and the second insulating layer S2 is disposed on the first insulating layer S1. According to an embodiment of the present disclosure, the steps for fabricating the first spacer SP1 and the second spacer SP2 may include sequentially forming the first insulating layer S1 and the second insulating layer S2 on the substrate 100 to cover the top surfaces and the side surfaces of the latitudinal gate structures 105, and then performing an anisotropic etching process to remove portions of the first insulating layer S1 and the second insulating layer S2 located on the surface of the substrate 100 and the top surfaces of the latitudinal gate structures 105, so as to obtain the first spacers SP1 on the two side surfaces of the first gate structures 105A and the second spacers SP2 on the two side surfaces of the second gate structures 105B.

Next, an etching step may be performed to remove a portion of at least one of the first spacers SP1, so that a height H1 (see FIG. 5) of the at least one of the first spacers SP1 is lower than a height H2 (see FIG. 5) of at least one of the second spacers SP2.

Please refer to FIG. 3 and FIG. 4. The etching step may include forming a dielectric material 107 on the substrate 100 firstly, in which the dielectric material 107 covers the first gate structures 105A and the second gate structures 105B, and the dielectric material 107 is filled in the spaces (not labeled) between the first gate structures 105A and the second gate structures 105B, and the spaces may be formed with contact plugs 28 (see FIG. 15) in the subsequent processes. According to an embodiment of the present disclosure, the dielectric material 107 includes silicon dioxide (SiO₂), but not limited thereto. The dielectric material 107 is separated from the active regions 102 and the isolation structure 104 by the insulating layer IL and does not contact the active regions 102 and the isolation structure 104 directly. Next, a patterned mask ML0 is formed on the dielectric material 107, in which the patterned mask ML0 includes the first recessed portions RP1 and the second recessed portions RP2, each of the first recessed portions RP1 corresponds to at least one of the first spacers SP1, each of the second recessed portions RP2 corresponds to the first gate structure 105A, and a bottom end RB1 of the first recessed portion RP1 is higher than a bottom end RB2 of the second recessed portion RP2. Specifically, the etching step may adopt a damascene process, which includes methods of trench first, via first, self-aligned, etc. The following explanation is based on the method of trench first. First, the first recessed portions RP1 are formed to define the trench pattern, and then the second recessed portions RP2 are formed to define the via pattern. Afterward, an etching process is performed to remove a portion of the dielectric material 107 to form the third recessed portions RP3 corresponding to the second recessed portions RP2 in the dielectric material 107.

As shown in FIG. 5, another etching process is performed to simultaneously remove the patterned mask ML0 and a portion of the dielectric material 107 to transfer the patterns of the first recessed portions RP1, the second recessed portions RP2, and the third recessed portions RP3 downwardly to expose the conductive layer 105b of the first gate structures 105A. Specifically, the mask layer 105c above the first gate structures 105A is removed to form the openings OP4, so that the conductive layer 105b of the first gate structures 105A is exposed. A portion of the first spacer SP1 is removed, so that the height H1 of the first spacer SP1 is lower than the height H2 of the second spacer SP2. At least a portion of the dielectric material 107 filled in the space between the first gate structure 105A and the second gate structure 105B is removed, so that the dielectric material 107 between the first gate structure 105A and the second gate structure 105B has a stepped cross section. Since only the first spacer SP1 adjacent to the opening OP4 has a portion being removed, the height H1 of the first spacer SP1 disposed adjacent to the opening OP4 is also lower than the height (identical to the height H2 of the second spacer SP2 in this embodiment) of other first spacer SP1 disposed at other position.

Please refer to FIG. 6. Next, a portion of the dielectric material 107 is removed by etching to form a plurality of openings OP that penetrate the dielectric material 107 and are equally spaced between the latitudinal gate structures 105, and then a dielectric material is formed to fill the openings OP, so as to obtain spacers 108 that are arranged with the dielectric material 107 alternately. The dielectric material 107 located between the spacers 108 become dielectric plugs. The dielectric material of the spacers 108 needs to be different from that of the dielectric material 107, so that the dielectric material 107 between the spacers 108 can be selectively removed in the subsequent processes. According to an embodiment of the present disclosure, if the dielectric material 107 is made of silicon dioxide (SiO₂), the spacers 108 may be made of silicon nitride (SiN). In some embodiments, the bottoms of the openings OP penetrate the insulating layer IL, so that each of the bottom surfaces of the spacers 108 directly contact the active region 102 or the isolation structure 104 of the substrate 100. In some embodiments, due to the etch loading effect caused by the change of the pattern density near the peripheral region PR, the bottoms of the openings OP in the peripheral region PR may be located at different depths in the isolation structure 104. Therefore, the bottom surfaces of the spacers 108 in the peripheral region PR may not be aligned with each other and extend to different depths in the isolation structure 104.

Please refer to FIG. 7. Next, a mask layer ML1 is formed to cover the main peripheral region PR1, the transition peripheral region PR2 and the transition unit region AR2 and to expose the main unit region AR1. Next, an etching process is performed to selectively remove the dielectric material 107 and the insulating layer IL directly below the dielectric material 107 in the main unit region AR1 exposed from the mask layer ML1. Thereby, a plurality of openings OP1 separated by the spacers 108 are formed in the main unit region AR1, and some of the active regions 102 of the substrate 100 are exposed. In some embodiments, the portions of the active regions 102 exposed from the openings OP1 are partially removed and slightly recessed downwardly, so that the bottom surfaces of the openings OP1 are lower than the bottom surfaces of the spacers 108. The mask layer ML1 is, for example, a patterned photoresist layer, but not limited thereto.

Please refer to FIG. 8. Next, the mask layer ML1 is removed and another mask layer ML2 is formed to cover the main peripheral region PR1 and to expose the transition peripheral region PR2, the transition unit region AR2 and the main unit region AR1. Then an etching process is performed to selectively remove the dielectric material 107 in the transition peripheral region PR2 and the transition unit region AR2 exposed from the mask layer ML2, so as to form a plurality of openings OP2 separated by the spacers 108 in the transition peripheral region PR2 and the transition unit region AR2. As shown in FIG. 8, the insulating layer IL at the bottom of each of the openings OP2 is not removed, so that each of the active regions 102 or the isolation structure 104 below the opening OP2 is not exposed. In other embodiments, the mask layer ML1 may not be removed after the openings OP1 are formed. Instead, a trimming process may be performed to trim the mask layer ML1, so that the mask layer ML1 is retreated toward the main peripheral region PRI to expose the transition peripheral region PR2 and the transition unit region AR2, and then an etching process is performed by using the trimmed mask layer ML1 as the etching mask to form the openings OP2.

Referring to FIG. 9 and FIG. 10, a semiconductor material 12 is formed to fill the openings OP1 and the openings OP2, and then a chemical mechanical polishing process or an etching process is performed to remove the semiconductor material 12 outside the openings OP1 and the openings OP2 and a portion of the mask layer ML2 (or the mask layer ML1) till the spacers 108 and the mask layer 105c above the second gate structures 105B are exposed. In some embodiments, the semiconductor material 12 includes polysilicon, but not limited thereto. In this embodiment, the semiconductor material 12 in the openings OP1 contacts the substrate 100 directly, and the semiconductor material 12 in the openings OP2 and the substrate 100 are separated by the insulating layer IL and do not contact with each other directly. Next, an etching process is performed to remove the remaining mask layer ML2 (or the mask layer ML1) to form openings OP4 to expose the conductive layer 105b of the first gate structures 105A, and then another mask layer (not shown) is formed to cover the regions other than the main peripheral region PR1. Next, an etching process is performed to selectively remove the dielectric material 107 in the main peripheral region PRI exposed from the mask layer, so as to form a plurality of openings OP3 in the main peripheral region PR1. As shown in FIG. 9 and FIG. 10, the openings OP3 are located above the isolation structure 104, and the insulating layer IL at the bottom of each of the openings OP3 is not removed, so that the isolation structure 104 is not exposed from the openings OP3.

Please refer to FIG. 11 and FIG. 12. First, the semiconductor material 12 in the openings OP1 and the openings OP2 is etched back until the remaining semiconductor material 12 is only filled in the lower portions of the openings OP1 and the openings OP2, and the upper portions of the openings OP1 and openings OP2 are exposed. Next, gate contact structures GC (see FIG. 15) are formed on the first gate structures 105A, which may include steps as follows. A gate contact material 16 is completely deposited on the unit region AR and the peripheral region PR. The gate contact material 16 covers the first gate structures 105A and the second gate structures 105B, and fills the openings OP1, OP2, OP3 and OP4. In some embodiments, the gate contact material 16 includes tungsten (W), but not limited thereto. In some embodiments, a height of the semiconductor material 12 in the openings OP1 and the openings OP2 is approximately between ½ depth and ⅓ depth of each of the openings OP1 and the openings OP2, but not limited thereto. In some embodiments, a metal silicide layer 14 may be included between the semiconductor material 12 and the gate contact material 16. The metal silicide layer 14 may be a single-layer structure or a multi-layer structure composed of titanium silicide (TiSi), tungsten silicide (WSi), cobalt silicide (CoSi), and/or other metal silicide materials, but not limited thereto.

Please refer to FIG. 13, FIG. 14 and FIG. 15. Next, a recessing process (such as a photolithography and etching process) is performed on the gate contact material 16, which includes removing the portion of the gate contact material 16 located above the second gate structures 105B and the portion of the gate contact material 16 located above some portions of the semiconductor material 12, and forming recesses R1 to pattern the gate contact material 16, so as to obtain connection pads 302, an embankment pad 304, extension pads 305 and interconnect structures 308 that are separated from each other, as well as contact plugs 22 in the openings OP1, contact plugs 24 in the openings OP2, contact plugs 26 in the openings OP3 located in the transition periphery region PR2, and contact plugs 28 in the openings OP3 and the contacts CT in the openings OP4 located in the main peripheral region PR1. As shown in FIG. 15, along the first direction D1, a contact plug 28 is defined between one of the first gate structures 105A and one of the second gate structures 105B. In this embodiment, the contact plugs 28 at two sides of one of the first gate structure 105A, the contact CT located on the one of the first gate structure 105A and the interconnection structure 308 located above the one of the first gate structure 105A together form the gate contact structure GC.

From a view point of function, the contact plug 22 is located on the end portion of the active region 102 and is configured to electrically connect the subsequently formed capacitor structure (not shown) and the drain of the transistor of the memory cell, i.e., the contact plug 22 is an interconnect contact plug for providing the electrical interconnection function. The contact plug 24, contact plug 26 and contact plug 28 are dummy contact plugs that can improve the process variation and structural strength. Due to the etch loading effect caused by the influence of the pattern density difference between the peripheral region PR and the unit region AR on the recessing process, as shown in FIG. 14, the depth of the recess R1 in the peripheral region PR is greater than the depth of the recess R1 in the unit region AR.

Each of the contact plug 22, the contact plug 24 and the contact plug 26 include a lower portion made of the semiconductor material 12 and an upper portion made of the gate contact material 16. The contact plug 28 is entirely made of the gate contact material 16. The lower portion of the contact plug 22 directly contacts the active region 102 and is electrically connected with the active region 102. The lower portion of the contact plug 24 is located on the insulating layer IL and is separated and electrically isolated from the active region 102. The contact plug 26 and the contact plug 28 are located on the isolation structure 104, and are separated from the isolation structure 104 by the insulating layer IL, i.e., the contact plug 26 and the contact plug 28 are not contact the isolation structure 104 directly. The connection pads 302, the embankment pad 304, the extension pads 305 and the interconnect structures 308 are made of the gate contact material 16. The connection pads 302 are disposed in the main unit region AR1, and each of the connection pads 302 is located on the contact plug 22 and integrally formed with the upper portion of the contact plug 22. The embankment pad 304 and the extension pads 305 are mainly disposed in the transition unit region AR2, in which the embankment pad 304 also extends across the boundary BN to the transition peripheral region PR2. The embankment pad 304 and the extension pads 305 may be located on some of the contact plugs 24, and the embankment pad 304 and the extension pads 305 are integrally formed with the upper portions of the contact plugs 24. The interconnection structures 308 are disposed in the main peripheral region PR1, and are disposed on the contacts CT and some of the contact plugs 28, and the interconnection structures 308 are integrally formed with the contacts CT and the contact plugs 28.

Next, a dielectric material (not labeled) is formed to fill the recesses R1 between the connection pads 302, the embankment pad 304 and the interconnection structures 308, and then a planarization process is performed to form a plurality of insulating structures 402 for ensuring the electrical isolation between the above structures. Specifically, some of the insulating structures 402 are disposed between the connection pads 302, one of the insulating structures 402 is disposed between the embankment pad 304 and the interconnection structure 308, some of the insulating structures 402 are disposed between the gate contact structures GC and are respectively disposed above the second gate structures 105B. According to an embodiment of the present disclosure, the insulating structure 402 includes silicon nitride (SiN), but not limited thereto.

At the stage of the process, the semiconductor structure according to the present disclosure is obtained. Please refer to FIG. 15, the semiconductor structure includes a substrate 100, a gate structure (such as the first gate structure 105A), two second contact plugs 28 and a gate contact structure GC. The gate structure is disposed on the substrate 100, the two contact plugs 28 are disposed on the substrate 100 and at two sides of the gate structure, the gate contact structure GC is disposed on the gate structure, and the gate contact structure GC is simultaneously connected with the two contact plugs 28 and the gate structure.

More specifically, the semiconductor structure includes the substrate 100, the first gate structures 105A, the first spacers SP1, the second gate structures 105B, the second spacers SP2, the gate contact structures GC and the insulating structures 402. The first gate structures 105A and the second gate structures 105B are disposed on the substrate 100, and the first gate structures 105A and the second gate structures 105B are alternately arranged in the first direction D1. Two first spacers SP1 are disposed oppositely on two side surfaces of one of the first gate structures 105A, and the two second spacers SP2 are disposed oppositely on two side surfaces of one of the second gate structures 105B. The gate contact structures GC are respectively disposed on the first gate structures 105A, the insulating structures 402 are between the gate contact structures GC and respectively disposed on the second gate structures 105B. A height H1 of at least one of the first spacer SP1 is lower than a height H2 of at least one of the second spacers SP2. Thereby, it is beneficial to lower the difficulty of aligning the first gate structure 105A and the gate contact structure GC, so as to reduce the fabrication difficulty and improve the process yield.

In this embodiment, the semiconductor structure further includes a mask layer 105c disposed on the second gate structures 105B. For the two first spacers SP1 at two sides of the same first gate structure 105A, a top of the mask layer 105c is higher than a top of at least one of the two first spacers SP1. Herein, the top of the mask layer 105c is higher than the tops of the two first spacers SP1, which is exemplary, and the present disclosure is not limited thereto.

In this embodiment, for the first spacers SP1 at two sides of the same first gate structure 105A, the top of at least one of the first spacers SP1 is higher than the top of the first gate structure 105A, and the bottom of the insulating structure 402 is higher than the top of at least one of the first spacers SP1.

In this embodiment, the heights H1 of the first spacers SP1 at two sides of the same first gate structure 105A are the same, the heights H2 of the second spacers SP2 at two sides of the same second gate structure 105B are the same, and the heights H1 of the first spacers SP1 at two sides of the same first gate structure 105A are lower than the heights H2 of the second spacers SP2 at two sides of the same second gate structure 105B. However, the present disclosure is not limited thereto. The heights H1 of the first spacers SP1 at two sides of the same first gate structure 105A may be different from each other, and the heights H2 of the second spacers SP2 at two sides of the same second gate structure 105B may be different from each other. The first gate structure 105A includes, from bottom to top, a semiconductor layer 105a and a conductive layer 105b. The gate contact structure CG physically contacts the conductive layer 105b of the first gate structure 105A. Two contact plugs are disposed at two sides of one of the first gate structures 105A along the first direction D1. In this embodiment, the contact plugs 28 located at two sides of the first gate structure 105A, the contact CT located on the first gate structure 105A and the interconnection structure 308 located above the first gate structure 105A are integrally formed and together form the gate contact structure GC. Therefore, the gate contact structure CG is disposed on two sides and the top surface of one of the first gate structures 105A. In addition, the two contact plugs 28 disposed at two sides of the first gate structure 105A may be regarded as two extending parts of the gate contact structure GC. In other words, the gate contact structure CG may also be regarded as including the two extending parts (not labeled) disposed in the two contact plugs 28.

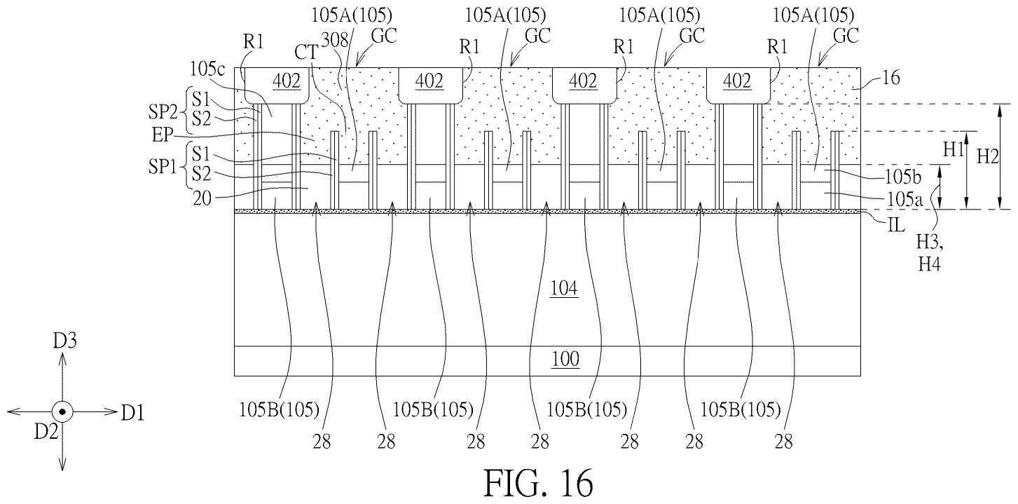

Please refer to FIG. 16. FIG. 16 is a schematic cross-sectional view of a semiconductor device according to another embodiment of the present disclosure, and the view angle thereof is identical to that of FIG. 15. The main difference between the semiconductor structure in FIG. 16 and the semiconductor structure in FIG. 15 is that the semiconductor structure in FIG. 16 further includes a material layer 20 disposed in the bottom of the contact plug 28. In this embodiment, the two extending parts EP at two sides of the first gate structure 105A, the contact CT located on the first gate structure 105A and the interconnection structure 308 located above the first gate structure 105A are integrally formed and together form the gate contact structure GC. The two extending parts EP of the gate contact structure CG are disposed on the material layer 20. The contact plug 28 includes a lower portion composed of the material layer 20 and an upper portion composed of the gate contact material 16 (i.e., the extending part EP of the gate contact structure GC). The height H3 of the material layer 20 may be the same as the height H4 of the first gate structure 105A. The material layer 20 may include a semiconductor material or a dielectric material.

The material of material layer 20 may be the same as the semiconductor material 12. For example, in the fabricating process of FIG. 8 to FIG. 11, the etching process may be performed without the mask layer ML2 to remove the dielectric material 107 in the main peripheral region PR1, the transition peripheral region PR2 and the transition unit region AR2, so that the openings OP2 and the openings OP3 may be formed simultaneously. Next, the semiconductor material 12 is formed to fill the openings OP1, OP2, OP3 and OP4, and the semiconductor material 12 in the openings OP1, OP2, OP3 and OP4 is etched back to be partially removed to obtain the contact plugs 22, 24, 28 with lower portions composed of the semiconductor material 12, and the semiconductor material 12 in the openings OP4 is completely removed to expose the conductive layer 105b of the first gate structures 105A. That is, the contact plugs 28 of the semiconductor structure in FIG. 15 may be changed to be fabricated together with the contact plugs 24, so that the structures of the contact plugs 28 and the contact plugs 24 are the same. Therefore, each of the contact plugs 28 may also selectively includes a metal silicide layer 14 disposed between the semiconductor material 12 and the gate contact material 16.

The material of the material layer 20 may be the same as that of the dielectric material 107. For example, in the fabricating process of FIG. 8 to FIG. 11, when forming the openings OP3, only the upper portion of the dielectric material 107 is removed, and the lower portion of the dielectric material 107 is reserved, so that the contact plugs 28 with the lower portions composed of the dielectric material 107 are obtained. In other words, the dielectric material 107 may be filled in the contact plugs 28 defined between the first gate structures 105A and the second gate structures 105B. Moreover, during the process of fabricating the contact plugs 28, at least a portion of the dielectric material 107 filled in the contact plugs 28 is removed.

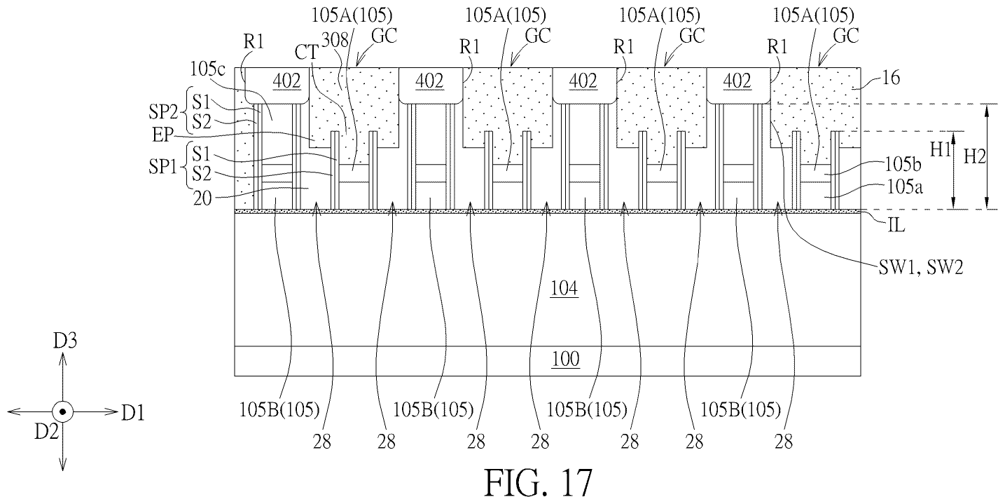

Please refer to FIG. 17, which is a schematic cross-sectional view of a semiconductor device according to yet another embodiment of the present disclosure, and the view angle thereof is identical to that of FIG. 15. The main difference between the semiconductor structure in FIG. 17 and the semiconductor structure in FIG. 16 is that the material layer 20 of the semiconductor structure in FIG. 17 includes a stepped cross section, so that the side surface SW1 of the material layer 20 physically contacts the side surface SW2 of the extending part EP. For example, the material of the material layer 20 may be the same as that of the dielectric material 107. In this case, in the fabricating process of FIG. 8 to FIG. 11, before forming the openings OP3, a patterned mask (not shown) may be formed to cover a portion of the dielectric material 107, and only the upper portion of the dielectric material 107 exposed from the patterned mask is removed, so that the material layer 20 includes the stepped cross section.

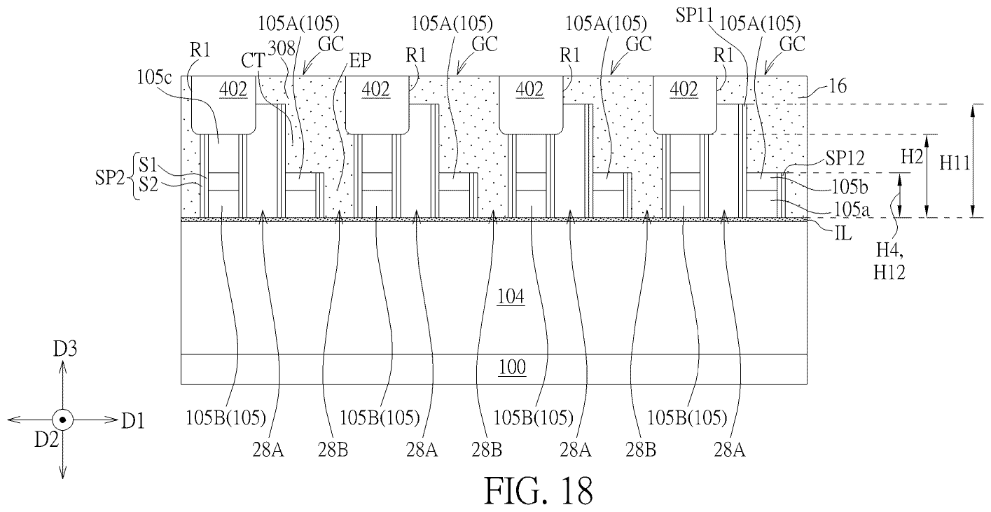

Please refer to FIG. 18, which is a schematic cross-sectional view of a semiconductor device according to yet another embodiment of the present disclosure, and the view angle thereof is identical to that of FIG. 15. For the convenience of explanation, difference reference signs are given to the first spacer SP11 at the left side of the first gate structure 105A and the first spacer SP12 at the right side of the first gate structure 105A, and different reference signs are given to the contact plug 28A at the left side of the first gate structure 105A and the contact plug 28B at the right side of the first gate structure 105A. The main differences between the semiconductor structure in FIG. 18 and the semiconductor structure in FIG. 15 are as follows. The heights H11 and H12 of the first spacers SP11 and SP12 at two sides of the same first gate structure 105A are different. Moreover, the materials filled in the contact plugs 28A and 28B at two sides of the same first gate structure 105A are different.

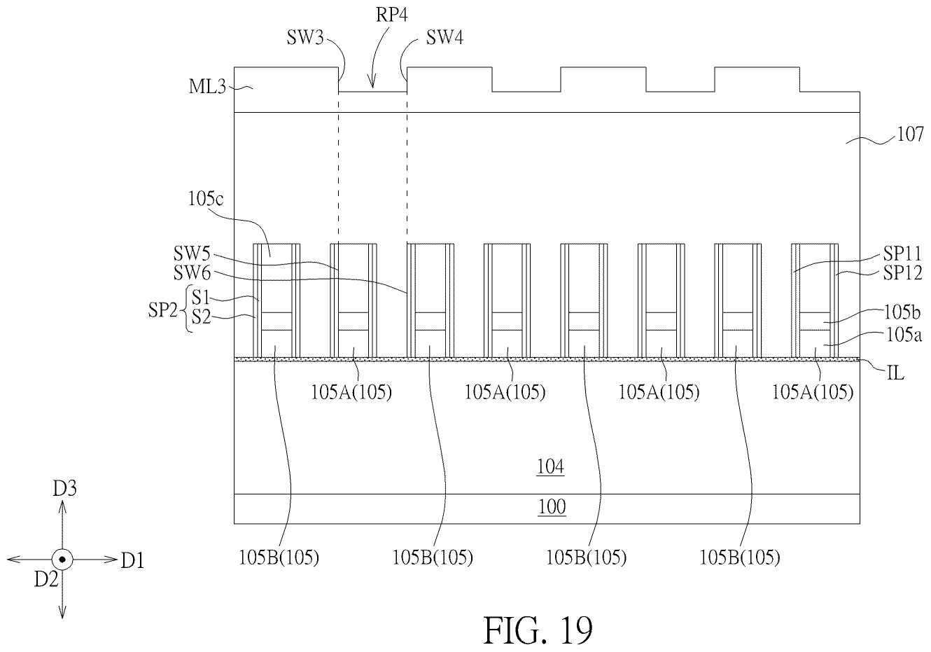

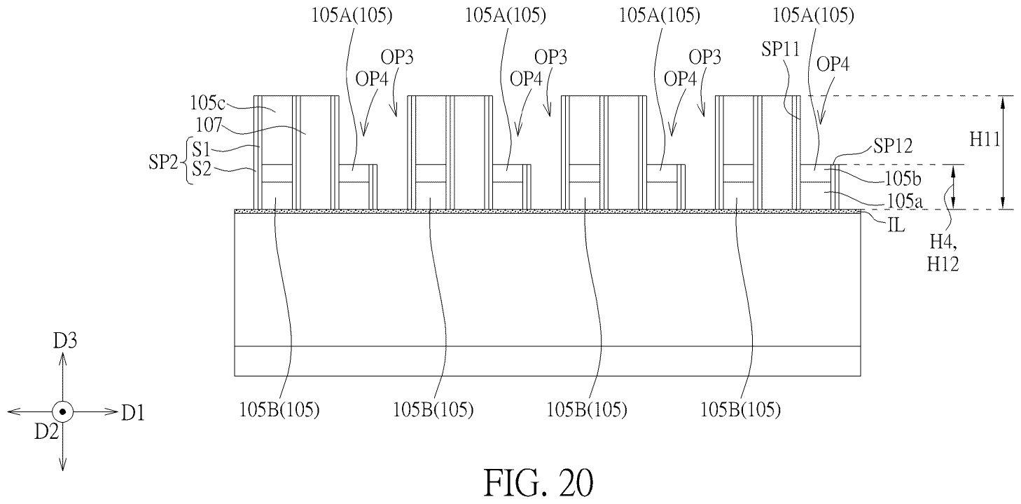

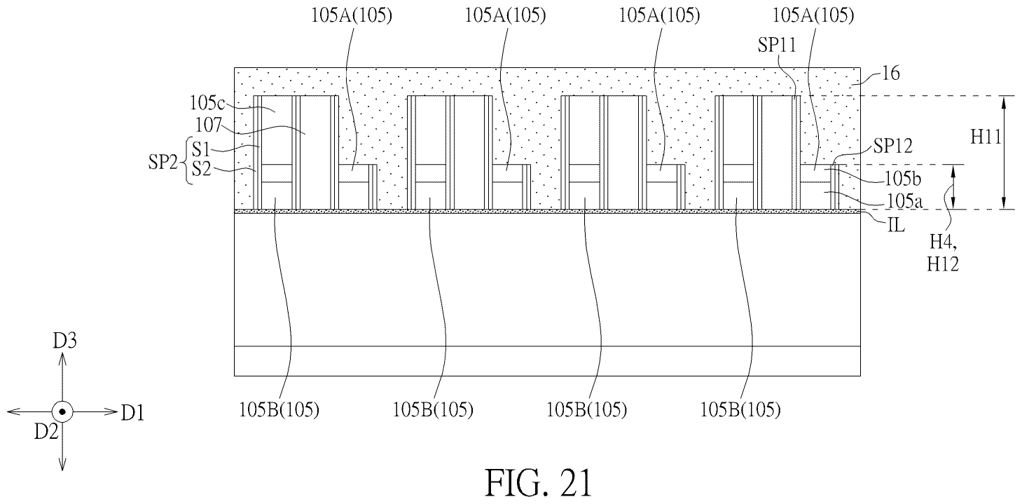

In the fabricating method of the semiconductor structure in FIG. 18, for example, the patterned mask ML0 in FIG. 4 may be replaced with the patterned mask ML3 in FIG. 19. The patterned mask ML3 includes the recessed portions RP4, and the side surface SW3 at the left side of each of the recessed portions RP4 is aligned with the inner side surface SW5 of the first spacer SP11, and the side surface SW4 at the right side of each of the recess portions RP4 is aligned with the outer side surface SW6 of the second spacer SP2. Next, an etching process is performed to simultaneously remove the patterned mask ML3 and the dielectric material 107 above the first gate structures 105A and the second gate structures 105B, and further to etch downwardly to remove the mask layer 105c on the first gate structures 105A, portions of the first spacers SP12, and the dielectric material 107 between the first spacer SP12 and the second gate structure 105B. Due to the mask layer 105c, the first spacer SP12 and the dielectric material 107 having different etching selectivity ratios, the mask layer 105c, the first spacer SP12 and the dielectric material 107 have different etching depths, in which the mask layer 105c on the first gate structures 105A is completely removed to form the openings OP4, so that the conductive layer 105b is exposed. The height H12 of the remaining first spacer SP12 is substantially the same as the height H4 of the remaining first gate structure 105A, and the dielectric material 107 located between the first spacer SP12 and the second gate structure 105B is completely removed to form the openings OP3. Thereby, the semiconductor structure shown in FIG. 20 can be obtained. Next, the steps shown in FIG. 6 to FIG. 12 may be performed, but the steps for forming the openings OP3 shown in FIG. 9 and FIG. 10 are omitted, so as to obtain the semiconductor structure shown in FIG. 21. Next, the steps shown in FIG. 13 to FIG. 15 are performed, in which a recessing process (such as a photolithography and etching process) is performed on the gate contact material 16, which includes steps as follows. A portion of the mask layer 105c on the second gate structures 105B, a portion of the second spacers SP2, a portion of the dielectric material 107 between the second gate structures 105B and first spacers SP11 and a portion of gate contact material 16 are removed to form the recesses R1 to pattern the gate contact material 16, and then the insulating structures 402 are formed in the recesses R1, so as to obtain the semiconductor structure shown in FIG. 18. For other details of fabricating the semiconductor structure shown in FIG. 18, a reference may be made to the relevant descriptions in FIG. 1 to FIG. 15, and are not repeated herein.

In FIG. 18, the heights H11 and H12 of the first spacer SP11 and SP12 at two sides of the first gate structure 105A are different, the heights H2 of the second spacers SP2 at two sides of the second gate structure 105B are the same, and the height H12 of the first spacer SP12 at the right side of the first gate structure 105A is lower than the height H2 of the second spacer SP2. The height H11 of the first spacer SP11 at the left side of the first gate structure 105A is higher than the height H2 of the second spacer SP2. In other words, in this embodiment, the heights H2 of the second spacers SP2 at two sides of the second gate structure 105B are the same, and the height H2 of the second spacer SP2 is between the height H11 of the first spacer SP11 and the height H12 of the first spacer SP12.

In this embodiment, the contact plug 28B located at the right side of the first gate structure 105A, the contact CT located on the first gate structure 105A and the interconnection structure 308 located above the first gate structure 105A are integrally formed and together form the gate contact structure GC. The gate contact material 16 disposed in the contact plug 28B may be regarded as the extending part EP of the gate contact structure GC. In other words, in this embodiment, the gate contact structure CG only includes the extending part EP disposed in the contact plug 28B and does not include the extending part (not labeled) disposed in the contact plug 28A, and thus the gate contact structure CG has an asymmetric cross section.

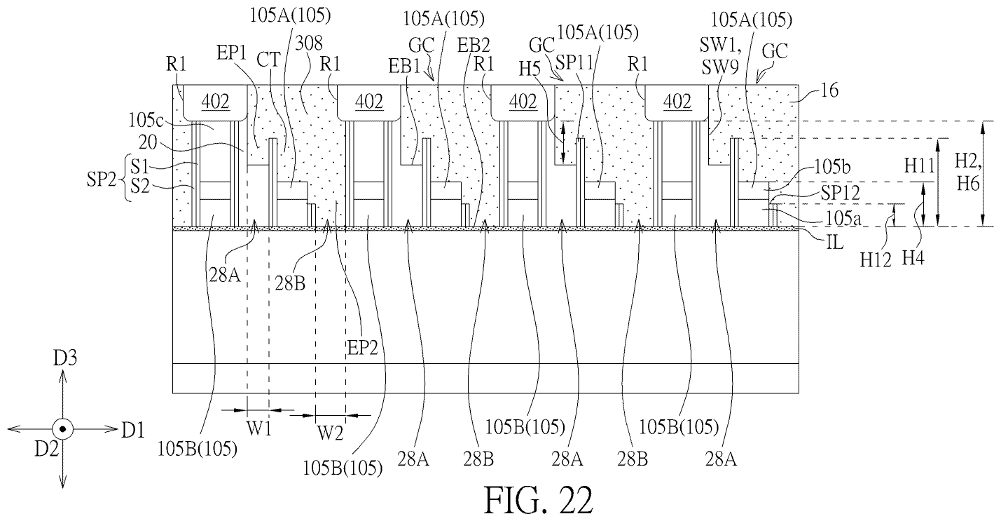

Please refer to FIG. 22, which is a schematic cross-sectional view of a semiconductor device according to yet another embodiment of the present disclosure, and the view angle thereof is identical to that of FIG. 15. For the convenience of explanation, difference reference signs are given to the first spacer SP11 at the left side of the first gate structure 105A and the first spacer SP12 at the right side of the first gate structure 105A, and different reference signs are given to the contact plug 28A at the left side of the first gate structure 105A and the contact plug 28B at the right side of the first gate structure 105A. The main differences between the semiconductor structures in FIG. 22 and FIG. 15 are as follows. The heights H11 and H12 of the first spacers SP11 and SP12 at two sides of the same first gate structure 105A are different. Moreover, the materials filled in the contact plugs 28A and 28B at two sides of the same first gate structure 105A are different.

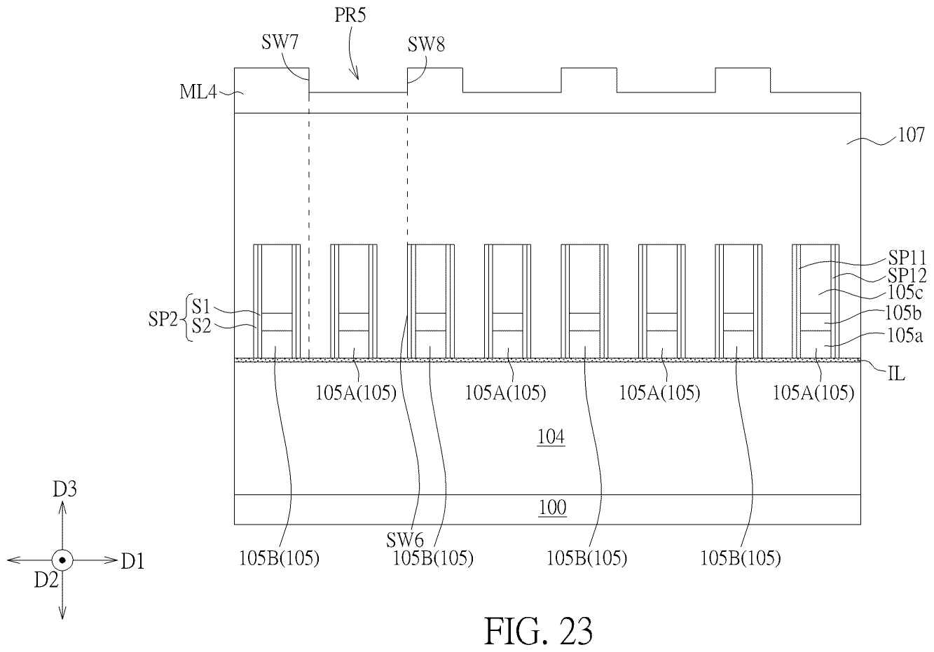

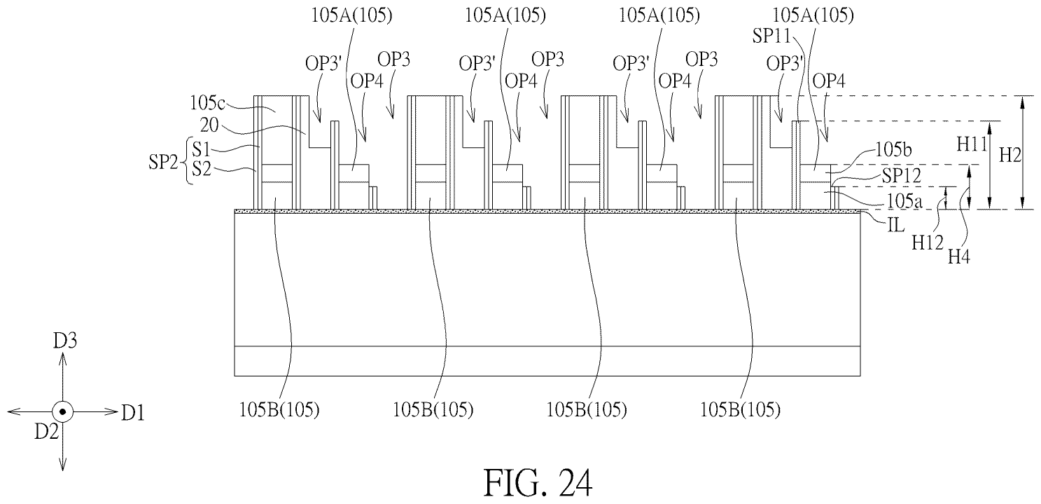

In the fabricating method of the semiconductor structure shown in FIG. 22, for example, the patterned mask ML0 in FIG. 4 may be replaced with the patterned mask ML4 in FIG. 23. The patterned mask ML4 includes recessed portions RP5, and the side surface SW7 at the left side of each of the recessed portions RP5 is aligned with the dielectric material 107 between the second gate structure 105B and the first spacer SP11, and the side surface SW8 at the right side of each of the recess portions RP5 is aligned with the outer surface SW6 of the second spacer SP2. Next, an etching process is performed to simultaneously remove the patterned mask ML4 and the dielectric material 107 above the first gate structures 105A and the second gate structures 105B, and further to etch downwardly to remove a portion of the dielectric material 107 between the second gate structure 105B and the first spacer SP11, a portion of the first spacer SP11, the mask layer 105c on the first gate structure 105A, a portion of the first spacer SP12, and a portion of the dielectric material 107 between the first spacer SP12 and the second gate structure 105B. Due to the factors, such as the mask layer 105c, the first spacers SP11 and SP12 and the dielectric material 107 having different etching selectivity ratios, the patterned mask ML4 having different thicknesses, the area of the dielectric material 107 between the second gate structure 105B and first spacer SP11 corresponding to the recessed portion RP5 being different the area of the dielectric material 107 between the first spacer SP12 and the second gate structure 105B corresponding to the recessed portion RP5, the dielectric material 107 between the second gate structure 105B and the first spacer SP11, the first spacer SP11, the mask layer 105c, the first spacer SP12, and the dielectric material 107 between the first spacer SP12 and the second gate structure 105B have different etching depths, in which a portion of the dielectric material 107 between the second gate structure 105B and the first spacer SP11 is removed to form the opening OP3′, a portion of the first spacer SP11 is removed, the mask layer 105c on the first gate structure 105A is completely removed to form the opening OP4 to expose the conductive layer 105b, a portion of the first spacer SP12 is removed, the height H12 of the remaining first spacer SP12 is lower than the height H4 of the first gate structure 105A, and the dielectric material 107 between the first spacer SP12 and the second gate structure 105B is completely removed to the opening OP3. Thereby, the semiconductor structure shown in FIG. 24 can be obtained. Moreover, because the material of the first spacer SP11 and the first spacer SP12 is similar to the material of the dielectric material 107, the first spacer SP11 and the first spacer SP12 may be etched to expose at least a portion of the conductive layer 105b of the first gate structure 105A or may be etched to simultaneously expose the conductive layer 105b and at least a portion of the semiconductor layer 105a of the first gate structure 105A. In FIG. 24, only the first spacer SP12 is etched to simultaneously expose the conductive layer 105b and a portion of the semiconductor layer 105a of the first gate structure 105A, which is exemplary, and the present disclosure is not limited thereto. For example, in some embodiment, both the first spacer SP11 and the first spacer SP12 are etched to expose at least a portion of the conductive layer 105b of the first gate structure 105A or etched to simultaneously expose the conductive layer 105b and at least a portion of the semiconductor layer 105a of the first gate structure 105A.

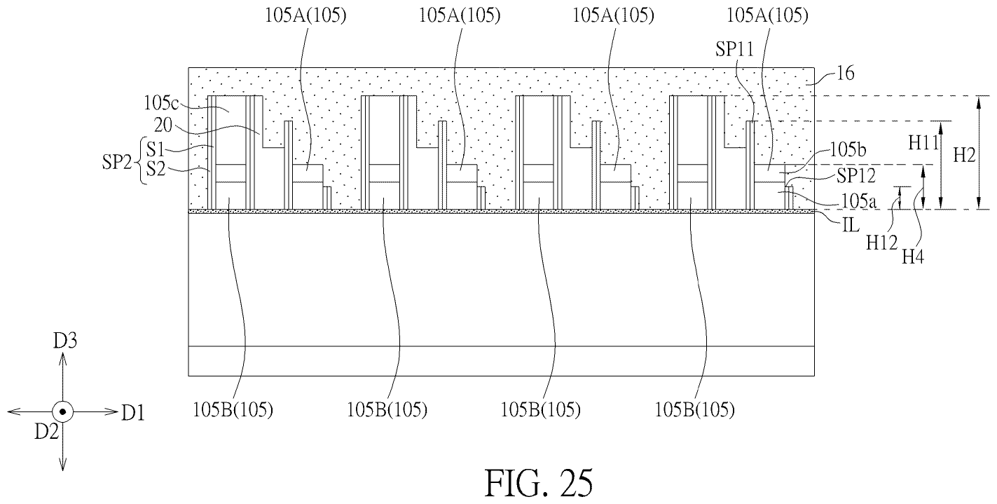

Next, the steps of FIG. 6 to FIG. 12 are formed, but the steps of forming the openings OP3 shown in FIG. 9 and FIG. 10 are omitted, so as to obtain the semiconductor structure shown in FIG. 25. In FIG. 25, since the first spacer SP12 is etched to expose the conductive layer 105b and a portion of the semiconductor layer 105a of the first gate structure 105A, the contact plug 28B contacts the right side surfaces of the conductive layer 105b and the semiconductor layer 105a of the first gate structure 105A directly. In other embodiment, when both the first spacer SP11 and the first spacer SP12 are etched to expose a portion of the conductive layer 105b of the first gate structure 105A, the contact plug 28A contacts the left side surface of the conductive layer 105b of the first gate structure 105A directly, and the contact plug 28B contacts the right side surface of the conductive layer 105b of the first gate structure 105A directly. In other embodiment, when both the first spacer SP11 and the first spacer SP12 are etched to expose the conductive layer 105b of the first gate structure 105A and a portion of the semiconductor layer 105a of the first gate structure 105A, the contact plug 28A contacts the left side surfaces of the conductive layer 105b and the semiconductor layer 105a of the first gate structure 105A directly, and the contact plug 28B contacts the right side surfaces of the conductive layer 105b and the semiconductor layer 105a of the first gate structure 105A directly. Next, the steps of FIG. 13 to FIG. 15 are performed, in which a recessing process (such as a photolithography and etching process) is performed on the gate contact material 16, which includes removing a portion of the gate contact material 16 to form recesses R1 to pattern the gate contact material 16, and forming the insulating structures 402 in the recesses R1, so as to obtain the semiconductor structure shown in FIG. 22. For other details of fabricating the semiconductor structure shown in FIG. 22, a reference may be made to the relevant descriptions in FIG. 1 to FIG. 15, and are not repeated herein.

In this embodiment, the heights H11 and H12 of the first spacers SP11 and SP12 at two sides of the first gate structure 105A are different, the heights H2 of the second spacers SP2 at two sides of the second gate structure 105B are the same, and the height H11 of the first spacer SP1 and the height H12 of the first spacer SP12 are all lower than the height H2 of the second spacer SP2.

In FIG. 22, the semiconductor structure further includes a material layer 20 disposed at the bottom of the contact plug 28A. The upper right portion of the contact plug 28A filled with the gate contact material 16, the contact plug 28B, the contact CT located on the first gate structure 105A, and the interconnection structure 308 located above the first gate structure 105A are integrally formed and together form the gate contact structure GC. The gate contact material 16 disposed in the upper right portion of the contact plug 28A may be regarded as the first extending part EP1 of the gate contact structure GC, and the gate contact material 16 disposed in the contact plug 28B may be regarded as the second extending part EP2 of the gate contact structure GC. In other words, in this embodiment, the gate contact structure GC includes the first extending part EP1 and the second extending part EP2 which are respectively disposed in the contact plug 28A and the contact plug 28B. In the contact plug 28A, the material layer 20 includes a stepped cross section, in which the side surface SW1 of the material layer 20 physically contacts the side surface SW9 of the first extending part EP1. The bottom end EB1 of the first extending part EP1 is higher than the bottom end EB2 of the second extending part EP2, and the height H5 of the first extending part EP1 in the third direction D3 perpendicular to the substrate 100 is smaller than the height H6 of the second extending part EP2 in the third direction D3. Therefore, the gate contact structure GC has an asymmetric cross section. Furthermore, the width W1 of the first extending part EP1 in the first direction D1 is smaller than the width W2 of the second extending part EP2 in the first direction D1.

To sum up, in the semiconductor structure according to the present disclosure, a plurality of first gate structures and a plurality of second gate structures are alternately arranged in the first direction, and the height of at least one of the first spacers disposed on the first gate structure is lower than the height of at least one of the second spacer disposed on the second gate structure. Thereby, it is beneficial to lower the difficulty of aligning the first gate structure and the gate contact structure, so as to reduce the fabrication difficulty and improve the process yield.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate;
a plurality of first gate structures disposed on the substrate;
two first spacers disposed oppositely on two side surfaces of one of the plurality of first gate structures;
a plurality of second gate structures disposed on the substrate, wherein the plurality of first gate structures and the plurality of second gate structures are alternately arranged in a first direction;
two second spacers disposed oppositely on two side surfaces of one of the plurality of second gate structures;
a plurality of gate contact structures respectively disposed on the plurality of first gate structures; and
a plurality of insulating structures disposed between the plurality of gate contact: structures and respectively disposed on the plurality of second gate structures;
wherein a height of at least one of the two first spacers is lower than a height of at least one of the two second spacers.

2. The semiconductor structure of claim 1, further comprising:
a mask layer disposed on the plurality of second gate structures, wherein a top of the mask layer is higher than a top of the at least one of the two first spacers.

3. The semiconductor structure of claim 1, wherein a top of the at least one of the two first spacers is higher than a top of the one of the plurality of first gate structures.

4. The semiconductor structure of claim 1, wherein a bottom of one of the insulating structures is higher than a top of the at least one of the first spacers.

5. The semiconductor structure of claim 1, wherein the plurality of gate contact structures are further respectively disposed at two sides and top surfaces of the plurality of first gate structures.

6. The semiconductor structure of claim 1, further comprising:
two contact plugs disposed at two sides of the one of the plurality of first gate structures along the first direction, and one of the plurality of gate contact structures comprises two extending parts disposed in the two contact plugs.

7. The semiconductor structure of claim 6, further comprising:
a material layer disposed in the two contact plugs, and a side surface of the material layer physically contacts a side surface of at least one of the two extending parts.

8. The semiconductor structure of claim 1, wherein the heights of the two first spacers are the same, and the heights of the two first spacers are all lower than the heights of the two second spacers.

9. The semiconductor structure of claim 1, wherein the heights of the two first spacers are different, and the height of at least one of the two first spacers is lower than the heights of the two second spacers.

10. The semiconductor structure of claim 1, wherein the heights of the two first spacers are different, the heights of the two second spacers are the same, and the height of at least one of the two first spacers is higher than the heights of the two second spacers.

11. The semiconductor structure of claim 6, wherein the two extending parts are respectively a first extending part and a second extending part, a bottom end of the first extending part is higher than a bottom end of the second extending part, and a height of the first extending part in a second direction perpendicular to the substrate is lower than a height of the second extending part in the second direction.

12. The semiconductor structure of claim 6, wherein the two extending parts are respectively a first extending part and a second extending part, a width of the first extending part in the first direction is less than a width of the second extending part in the first direction.

13. A method for fabricating a semiconductor structure, comprising:
providing a substrate;
forming a plurality of first gate structures and a plurality of second gate structures alternately arranged in a first direction on the substrate;
forming two first spacers on two side surfaces of one of the plurality of first gate structures and two second spacers on two side surfaces of one of the plurality of second gate structures;
performing an etching step to remove a portion of at least one of the two first spacers, so that a height of the at least one of the two first spacers is lower than a height of at least one of the two second spacers;
forming a plurality of gate contact structures respectively on the plurality of first gate structures; and
forming a plurality of insulating structures between the plurality of gate contact structures and respectively on the plurality of second gate structures.

14. The method of claim 13, wherein performing the etching step further comprises:
forming a dielectric material to cover the plurality of first gate structures and the plurality of second gate structures;
forming a patterned mask on the dielectric material, wherein the patterned mask comprises a first recessed portion corresponding to the at least one of the two first spacers; and
removing the dielectric material to expose a conductive layer of the one of the plurality of first gate structures.

15. The method of claim 14, wherein the patterned mask further comprises a second recessed portion, a bottom end of the first recessed portion is higher than a bottom end of the second recessed portion, and the second recessed portion corresponds to the one of the plurality of first gate structures.

16. The method of claim 15, wherein the dielectric material comprises a third recessed portion corresponding to the second recessed portion.

17. The method of claim 14, wherein a plurality of contact plugs are defined between the plurality of first gate structures and the plurality of second gate structures along the first direction, and the dielectric material is filled in the plurality of contact plugs.

18. The method of claim 17, further comprising:
removing at least a portion of the dielectric material filled in the contact plugs.

19. The method of claim 13, wherein forming the plurality of gate contact structures comprises:
depositing a gate contact material covering the plurality of first gate structures and the plurality of second gate structures; and
removing a portion of the gate contact material located above the plurality of second gate structures.

20. A semiconductor structure, comprising:
a substrate;
a gate structure disposed on the substrate;
two contact plugs disposed on the substrate and at two sides of the gate structure; and
a gate contact structure disposed on the gate structure, wherein the gate contact structure is simultaneously connected with the two contact plugs and the gate structure.
